(19) United States
(12) Patent Application Publication
(10) Pub. No.: US 2025/0191988 A1
(43) Pub. Date: Jun. 12, 2025

(54) HEAT DISSIPATION THROUGH SEAL RINGS

(71) Applicant: Taiwan Semiconductor Manufacturing Company, Ltd., Hsinchu (TW)

(72) Inventors: Yung-Shih Cheng, Hsinchu City (TW); Wen-Sheh Huang, Hsinchu City (TW)

(21) Appl. No.: 18/531,189

(22) Filed: Dec. 6, 2023

(51) Int. Cl. H01L 23/31; H01L 23/522; H01L 27/02; H01L 27/06; H01L 29/06; H01L 29/423; H01L 29/66; H01L 29/775; H01L 29/786; H01L 29/788; H01L 29/861

(52) U.S. Cl. CPC H01L 23/3114; H01L 23/5226; H10D 8/411; H10D 30/43; H10D 30/6735; H10D 30/6757; H10D 30/68; H10D 62/121; H10D 64/018; H10D 84/811; H10D 89/10; H10D 89/611

(57) ABSTRACT

An integrated chip (IC) device according to the present disclosure includes a device region, an interconnect structure disposed over the device region, and a seal ring surrounding the device region and the interconnect structure. The device region includes a transistor having a gate structure. The seal ring includes a metal structure. The gate structure is thermally coupled to the metal structure by way of a diode.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For semiconductor devices fabricated on a bulk semiconductor substrate, the bulk semiconductor substrate may serve as a heat sink to pull away heat generated by the semiconductor devices. In some technology where the semiconductor substrate is thinned or substantially removed, the semiconductor devices cannot dissipate heat through the semiconductor substrate and other thermal paths or sinks are needed. When heat of semiconductor devices cannot be effectively dissipated, performance of the semiconductor devices may suffer.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a top view of a substrate and a top view of an integrated circuit chip (IC) on the substrate, according to one or more aspects of the present disclosure.

FIG. 2 illustrates a cross-sectional view of the IC chip in FIG. 1, according to one or more aspects of the present disclosure.

FIG. 3 schematically illustrates a cross-sectional view of a heat conduction pathways between a device region and a seal ring surrounding the device region, according to one or more aspects of the present disclosure.

FIGS. 4 and 5 illustrates a fragmentary cross-sectional view of a diode in connection with a gate structure of a transistor and a metal structure in a seal ring, according to one or more aspects of the present disclosure.

FIG. 6 schematically illustrates a top view of an IC chip with heat conduction pathways between a device region and a metal structure of a seal ring, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed. For avoidance of doubts, the X, Y and Z directions in figures of the present disclosure are perpendicular to one another. Throughout the present disclosure, like reference numerals denote like features, unless otherwise excepted.

For semiconductor devices fabricated on a bulk semiconductor substrate, the bulk semiconductor substrate may serve as a heat sink to pull away heat generated by the semiconductor devices. In some technology where the semiconductor substrate is thinned or substantially removed, the semiconductor devices cannot dissipate heat through the semiconductor substrate and other thermal paths or sinks are needed. When heat of semiconductor devices cannot be effectively dissipated, performance of the semiconductor devices may suffer. For example, when front-end-of-line (FEOL) devices are interconnected through both a frontside interconnect structure and a backside interconnect structure. The semiconductor substrate on which the FEOL devices are fabricated may be thinned from more than 750 μm to well less than 1 μm such that backside contacts can be formed to electrically couple to the FEOL devices. The thinned semiconductor substrate may not be continuous because several dielectric isolation structures, such as shallow trench isolation (STI) features may be present to isolation adjacent FEOL devices. Besides these isolation structures, the frontside and backside interconnect structures also include dielectric materials. The dielectric material of the isolation features and in the interconnect structures has a thermal conductivity that is at least two order of magnitude smaller than that of semiconductor substrates. Because the FEOL devices are surrounded by these poor heater conductors, it is challenging to satisfactorily dissipate heat generated during operation of the FEOL devices.

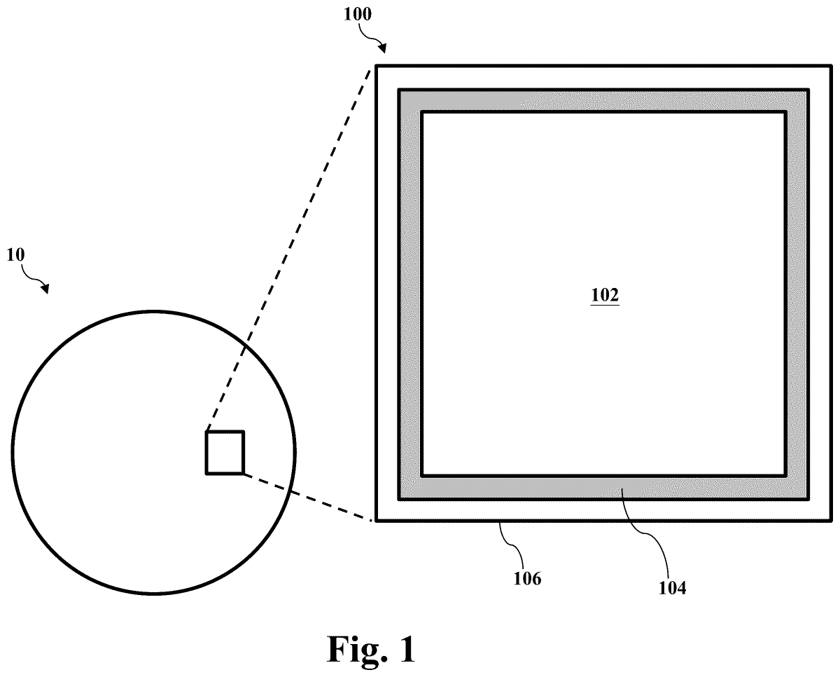

FIG. 1 illustrates a schematic top view of an integrated circuit (IC) chip 100 fabricated on a semiconductor wafer 10. As shown in FIG. 1, the IC chip 100 may be rectangular in shape. The IC chip 100 includes a device region 102 that includes FEOL devices as well as back-end-of-line (BEOL) structures, such as interconnect structures. To prevent the device region 102 from being damaged due to mist ingress or stress generated during singulation of the IC chip 100, the IC chip 100 includes a seal ring 104 that completely surrounds the device region 102. Boundaries of the IC chip 100 are defined by a scribe line 106, along which the IC chip 100 may be diced or singulated from the semiconductor wafer 10. The seal ring 104 is disposed between the device region 102 and the scribe line 106. As described above, the seal ring 104 functions to prevent the device region 102 from being damaged by the stress generated when dicing happens along the scribe line 106.

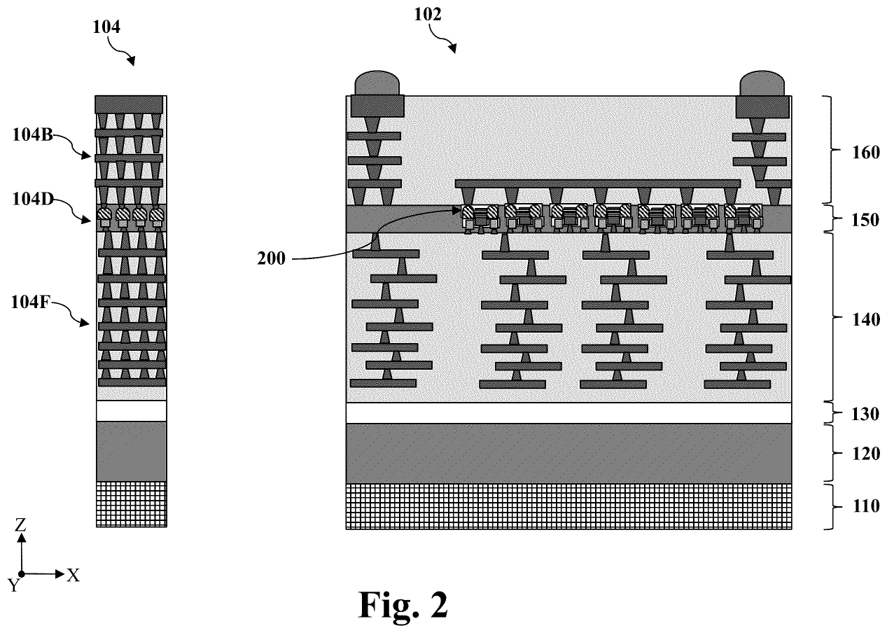

FIG. 2 provides fragmentary cross-sectional views of the seal ring 104 and the device region 102 shown in FIG. 1. Attention is first directed to the device region 102. The device region 102 includes an FEOL layer 150 that includes transistors 200. The transistors 200 may be planar devices or multi-gate devices. A planar device refers to a device having a gate structure engaging one side of a channel region. As integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors (both also referred to as non-planar transistors) are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). Compared to planar transistors, such configuration provides better control of the channel and drastically reduces SCEs (in particular, by reducing sub-threshold leakage (i.e., coupling between a source and a drain of the FinFET in the “off” state)). A GAA transistor has a gate structure that can extend, partially or fully, around a channel region to provide access to the channel region on two or more sides. Due to this configuration, a GAA transistor may also be referred to as a surrounding-gate transistor (SGT) or a multi-bridge-channel (MBC) transistor. The channel region of the GAA transistor may be formed from nanowires, nanosheets, other nanostructures, and/or other suitable structures. These shapes of the channel region also give a GAA transistor different names. For example, a GAA transistor with nanosheet channel regions may be referred to as a nanosheet transistor. In the depicted embodiments, the transistors 200 are GAA transistors. Because the gate structure extends through narrow spaces, heat dissipation from the gate structure may be hampered as well.

As dimensions of the transistors 200 in the FEOL layer 150 continue to shrink, a single interconnect structure on one side of the FEOL layer 150 may not be sufficient to satisfactorily route the signals. As illustrated in the FIG. 2, the device region 102 includes a frontside interconnect structure 140 and a backside interconnect structure 160. In some embodiments, the frontside interconnect structure 140 may include 9 to 14 metallization layers and the backside interconnect structure 160 may include 3 to 6 metallization layers. Each of the metallization layers includes conductive lines and contact vias embedded in an intermetal dielectric (IMD) layer. The IMD layer may include materials such as tetraethylorthosilicate (TEOS) oxide, un-doped silicate glass, or doped silicon oxide, borophosphosilicate glass (BPSG), fused silica glass (FSG), phosphosilicate glass (PSG), boron doped silicon glass (BSG), silicon oxycarbide, and/or other suitable dielectric materials. The conductive lines and contact vias may include copper (Cu), titanium nitride (TiN), tungsten (W), or ruthenium (Ru). The interconnect structures functionally connect semiconductor devices, such as transistors 200 in the IC chip 100. In some embodiments not explicitly shown in the figures, active and passive devices may be included in the frontside interconnect structure 140 and/or the backside interconnect structures 160. Examples of such active and passive devices may include, for example metal-insulator-metal (MIM) capacitors, radio frequency (RF) antennas, deep trench capacitors, memory devices, or transistors.

In some embodiments, after structures in the FEOL layer 150 are formed on a substrate, such as the semiconductor wafer 10 shown in FIG. 1, the frontside interconnect structure 140 is formed over the transistors 200. A bonding dielectric layer 130 is deposited over the frontside interconnect structure 140. In some instances, the bonding dielectric layer 130 may include silicon oxide. By way of the bonding dielectric layer 130, the frontside interconnect structure 140, along with the FEOL layer 150 and the semiconductor wafer 10, is turned upside down and bonded to a carrier wafer 120, which may include a semiconductor material, sapphire, quartz, or glass. The carrier wafer 120 is attached to a chuck 110 by use of electromagnetic force or vacuum suction. Before the backside interconnect structure 160 can be formed, the semiconductor wafer 10 is subject to grinding and polishing to reduce its thickness from between about 750 μm and about 800 μm to between about 10 nm and about 100 nm. After the thickness reduction, backside contacts are formed and the backside interconnect structure 160 are formed to connect to the transistors 200 by way of these backside contacts. The leftover semiconductor wafer 10 may be considered a part of the FEOL layer 150 in FIG. 2. In some technologies, the semiconductor wafer 10 may serve as a heat sink because semiconductor materials possess good thermal conductivity and its volume is orders of magnitude greater than the transistors 200. However, as shown in FIG. 2, when the device region 102 includes both the frontside interconnect structure 140 and the backside interconnect structure 160, more than 99.9% of the semiconductor wafer 10 may be removed. The volume of the semiconductor wafer 10 is greatly reduced too. Additionally, heat conduction from the FEOL layer 150 is hindered by several dielectric layers that may include silicon oxide. Because thermal conductivity of silicon oxide is more than two orders of magnitude smaller than that of silicon, heat dissipation from the transistors 200 in the device region 102 can be challenging.

The seal ring 104 is not only present in the FEOL layer 150 but also in the frontside interconnect structure 140 and the backside interconnect structure 160. As shown in FIG. 2, the seal ring 104 includes through-substrate contact structures 104D in the FEOL layer 150, a frontside seal ring wall 104F in the frontside interconnect structure 140, and a backside seal ring wall 104B in the backside interconnect structure 160. The through-substrate contact structures 104D may include multiple stacks of a backside contact via, an epitaxial feature over the backside contact via, an epitaxial contact feature over the epitaxial feature, and a contact via over the epitaxial contact feature. With the except of the epitaxial features, the backside contact via, the epitaxial contact feature and the contact via may include ruthenium (Ru), copper (Cu), nickel (Ni), cobalt (Co), titanium nitride (TiN) or tungsten (W). The frontside seal ring wall 104F includes metallization layers where the contact vias are vertically aligned. Like the frontside seal ring walls 104F, the backside seal ring wall 104B also includes metallization layers where the contact vias are vertically aligned. While FIG. 2 also shows a single frontside seal ring wall and a singe backside seal ring wall, both the frontside seal ring wall 104F and the backside seal ring wall 104B may include multiple ring walls. In some embodiments, the frontside seal ring walls 104F and the backside seal ring wall 104B may include copper (Cu), nickel (Ni), cobalt (Co), or titanium nitride (TiN).

The present disclosure is directed to structures for dissipating heat generated in the device region 102 to the seal ring 104. While the seal ring 104 is intended to prevent mist ingress and stress from damaging the device region, the seal ring 104 includes a rather large metal structure. As shown in FIG. 2, the frontside seal ring wall 104F is electrically coupled to the backside seal ring wall 104B by the through-substrate contact structures 104D to form an electrically conductive enclosure of the device region 102. Because thermal conductivity is proportional to electrical conductivity in all materials, the electrically conductive seal ring 104 may also serve as a good thermal conductor.

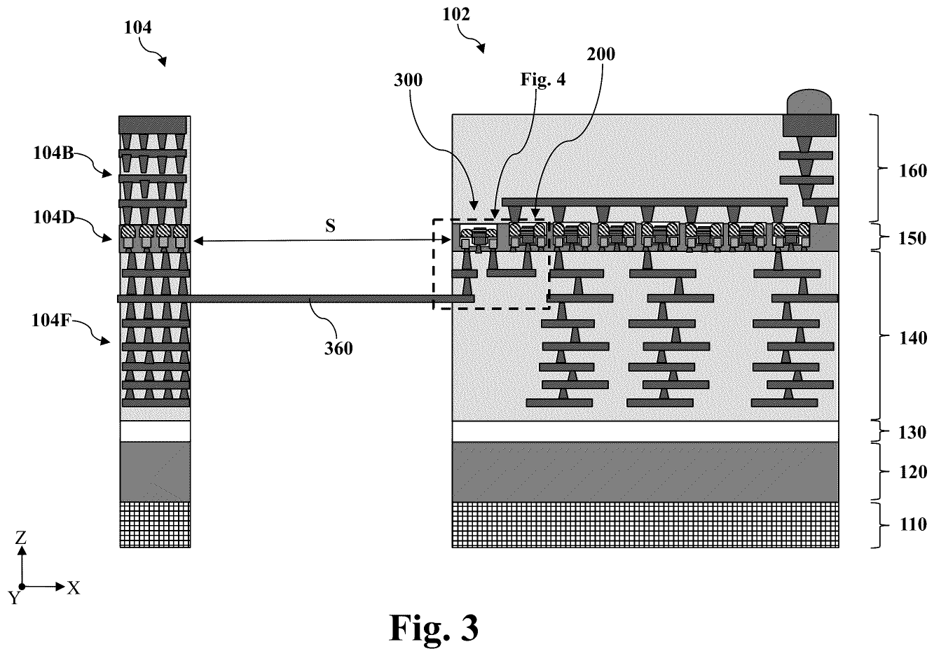

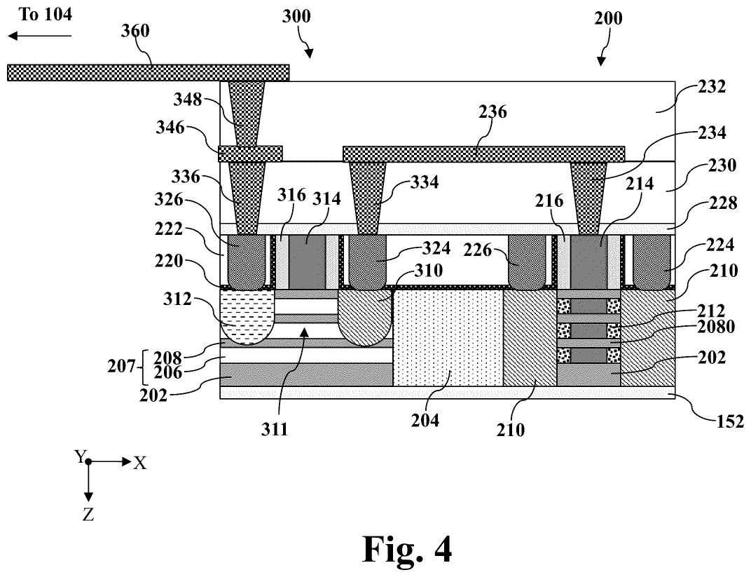

FIG. 3 illustrates a heat dissipation structure according to one or more aspects of the present disclosure. It has been observed that when the transistors 200 are GAA devices, heat is most likely accumulated in the gate structure that wraps around a vertical stack of channel members. Additionally, the gate structure is most likely to be impacted as excessive heat may cause threshold voltage shifting. For these reasons, a gate contact via connecting to the gate structure is an effective gateway to undesirable heat. By way of a first metal line coupling to the gate contact via, a first contact via and a first contact, the gate contact via is thermally and electrically coupled to a first doped region of a lateral diode 300. A second doped region of the lateral diode 300 is thermally and electrically coupled to the seal ring 104 by way of a second contact, a second contact via, a second metal line, a connection via, and a third metal line 360. The third metal line 360 extends laterally across a spacing S between the device region 102 and the seal ring 104. The spacing S is for buffering and is selected in consideration of heat conduction in a form of waves. When the spacing S is too small, heat wave propagating toward the seal ring 104 from the device region 102 may bounce back too quickly, causing inefficient heat dissipation from the device region 102. In some embodiments, the first doped region is doped with an n-type dopant and the second doped region is doped with a p-type dopant. The lateral diode 300 functionally serves as a filter. The lateral diode 300 allows heat passage to the seal ring 104 but prevents the seal ring 104 from being electrically coupled to the gate structure. As will be explained further below, gate structures of multiple transistors 200 are thermally coupled to the seal ring 104. Without the lateral diode 300, gate structures of all of these transistors 200 would be shorted together and have the same potential. To better illustrates the structures and connections, a dotted-line portion of FIG. 3 is enlarged and shown in FIG. 4.

Reference is now made to FIG. 4. The transistor 200 may be a transistor in a standard cell that includes multiple transistors. In the illustrated embodiment, the transistor 200 has a GAA construction. A plurality of channel members 2080 are vertically stacked one over another over a doped substrate portion 202. The plurality of channel members 2080 and the doped substrate portion 202 extend between two source/drain features 210 along the X direction. A gate structure 214 wraps around each of the channel members 2080 and comes in contact with a top surface of the doped substrate portion 202. The gate structure 214 is spaced apart from the two source/drain features 210 by a plurality of inner spacer features 212. The plurality of inner spacer features 212 interleave the plurality of channel members 2080 along the Z direction. A first source/drain contact 224 and a second source/drain contact 226 are disposed over and electrically coupled to the two source/drain features 210, respectively. A top portion of the gate structure 214 is lined by top gate spacers 216. As shown in FIG. 4, the gate structure 214 is laterally spaced apart from the first source/drain contact 224 and the second source/drain contact 226 by the top gate spacers 216. The first source/drain contact 224 and the second source/drain contact 226 extend through a contact etch stop layer (CESL) 220 and a first interlayer dielectric (ILD) layer 222 to couple to the source/drain features 210. In some embodiments illustrated in FIG. 4, the transistor 200 is disposed on a backside dielectric layer 152. The backside dielectric layer 152 may include silicon oxide or silicon nitride.

In some embodiments, the plurality of channel members 2080 include silicon (Si). The plurality of channel members 2080 is disposed over the doped substrate portion 202, which is formed from a bulk semiconductor substrate. In some embodiments, the bulk semiconductor substrate may be a silicon (Si) substrate. In some other embodiments, the bulk semiconductor substrate includes elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In some implementations, the bulk semiconductor substrate includes one or more group III-V materials, one or more group II-VI materials, or combinations thereof. In still some instances, the bulk semiconductor substrate is a semiconductor-on-insulator substrate, such as a silicon-on-insulator (SOI) substrate, a silicon germanium-on-insulator (SGOI) substrate, or a germanium-on-insulator (GeOI) substrate. In still some embodiments, the bulk semiconductor substrate may be diamond substrate or a sapphire substrate. The doped substrate portion 202 may include an n-type dopant, such as phosphorus (P) or arsenic (As), or a p-type dopant, such as boron (B). When doped with an n-type dopant, the doped substrate portion 202 may be referred to as an n-well. When doped with a p-type dopant, the doped substrate portion 202 may be referred to as a p-well. The doped substrate portion 202 has a conductivity different from the transistor 200 disposed thereon. When the transistor 200 is an n-type transistor, the doped substrate portion 202 is a p-well. When the transistor 200 is a p-type transistor, the doped substrate portion 202 is an n-well.

The gate structure 214 includes a gate dielectric layer and a gate electrode layer over the gate dielectric layer. In some embodiments, the gate dielectric layer includes an interfacial layer to interface the channel members 2080 and a high-K gate dielectric layer over the interfacial layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed using ALD, PVD, CVD, e-beam evaporation, or other suitable process.

The source/drain features 210 may include silicon (Si) doped with an n-type dopant, such as phosphorus (P) or arsenic (As) or silicon germanium (SiGe) doped with a p-type dopant, such as boron (B) or boron difluoride (BF₂). In the depicted embodiments, the transistor 200 in FIG. 4 is an n-type transistor and the source/drain features 210 includes silicon (Si) and an n-type dopant. The inner spacer features 212 space the gate structure 214 from the source/drain features 210 and may include silicon nitride, silicon oxycarbonitride, silicon oxynitride, or silicon oxycarbide. The top gate spacers 216 define the gate trench in a gate replacement process and may include silicon nitride, silicon oxycarbonitride, silicon oxynitride, or silicon oxycarbide. The first source/drain contact 224 and the second source/drain contact 226 may include a barrier layer, a silicide layer, and a metal fill layer disposed over the silicide layer. The barrier layer may include titanium nitride or tantalum nitride and functions to prevent electro-migration in the metal fill layer. The silicide layer may include titanium silicide, tantalum silicide, cobalt silicide, nickel silicide, or tungsten silicide. The silicide layer is disposed at the interface between the metal fill layer and the source/drain features 210 to reduce contact resistance. The metal fill layer may include ruthenium (Ru), copper (Cu), nickel (Ni), cobalt (Co), or tungsten (W). The CESL 220 may include silicon nitride or silicon oxynitride. The first ILD layer 222 may include silicon oxide.

FIG. 4 also illustrates a lateral diode 300 disposed on the backside dielectric layer 152. The lateral diode 300 includes an active region that includes a vertical stack 207 of first semiconductor layers 208 and second semiconductor layers 206, where the latter interleave the former. The stack 207 are disposed on the doped substrate portion 202. In some embodiments, the first semiconductor layers 208 include silicon (Si) and the second semiconductor layers 206 include silicon germanium (SiGe). The lateral diode 300 also include a dummy gate structure 314 that is disposed between two portions of a top gate spacer 316. Unlike the gate structure 214 of the transistor 200, the dummy gate structure 314 is disposed over a top surface of the stack without wrapping around any of the first semiconductor layers 208 because the first semiconductor layers 208 in the lateral diode 300 are never released to form suspended channel members. Additionally, unlike the gate structure 214, the dummy gate structure 314 is not electrically coupled to any conductive structure and is left electrically floating. The lateral diode 300 in FIG. 4 includes a first doped region 310 and a second doped region 312 that extend vertically and partially into the stack 207 but are spaced apart from one another along the X direction. The first doped region 310 and the second doped region 312 include different kinds of dopants and have different conductivity types. In the depicted embodiment, the first doped region 310 is doped with an n-type dopant, such as phosphorus (P) or arsenic (As) and is an n-type doped region. The second doped region 312 is doped with a p-type dopant, such as boron (B) and is a p-type doped region. In the depicted embodiments, the n-type first doped region 310 and the p-type second doped region 312 form a p-n junction diode. The n-type first doped region 310 serves as the cathode and the p-type second doped region 312 serves as the anode. The region under the dummy gate structure 314, being disposed between the n-type first doped region 310 and the p-type second doped region 312 along the X direction, serves as a depletion region 311 of the lateral diode 300.

The lateral diode 300 also includes a first contact 324 disposed over and electrically coupled to the first doped region 310 and a second contact 326 disposed over and electrically coupled to the second doped region 312. The first contact 324 and the second contact 326 may include a barrier layer, a silicide layer, and a metal fill layer disposed over the silicide layer. The barrier layer may include titanium nitride or tantalum nitride and functions to prevent electro-migration in the metal fill layer. The silicide layer may include titanium silicide, tantalum silicide, cobalt silicide, nickel silicide, or tungsten silicide. The silicide layer is disposed at the interface between the metal fill layer and the first doped region 310 or the second doped region 312 to reduce contact resistance. The metal fill layer may include ruthenium (Ru), copper (Cu), nickel (Ni), cobalt (Co), or tungsten (W). As shown in FIG. 4, the dummy gate structure 314 is laterally spaced apart from the first contact 324 and the second contact 326 by top gate spacers 316. In some embodiments, the top gate spacers 216 of the transistor 200 and the top gate spacers 316 of the lateral diode 300 may share similar dimensions and compositions. The first contact 324 and the second contact 326 extend through the contact etch stop layer (CESL) 220 and the first interlayer dielectric (ILD) layer 222 to couple to the first doped region 310 and the second doped region 312, respectively. The transistor 200 and the lateral diode 300 are spaced apart from one another along the X direction by an isolation structure 204, which may be a shallow trench isolation (STI) feature. The isolation structure 204 may include silicon oxide, tetraethylorthosilicate (TEOS) oxide, un-doped silicate glass, or doped silicon oxide, borophosphosilicate glass (BPSG), fused silica glass (FSG), phosphosilicate glass (PSG), boron doped silicon glass (BSG), silicon oxycarbide, and/or other suitable dielectric materials.

Referring to FIG. 4, top surfaces of the first source/drain contact 224, the gate structure 214, the top gate spacers 216, the second source/drain contact 226, the first contact 324, the dummy gate structure 314, the top gate spacers 316, the second contact 326, the CESL 220, and the first ILD layer 222 are substantially coplanar due to a planarization process, such as a chemical mechanical polishing (CMP) process. An etch stop layer (ESL) 228 is disposed over top surfaces of the first source/drain contact 224, the gate structure 214, the top gate spacers 216, the second source/drain contact 226, the first contact 324, the dummy gate structure 314, the top gate spacers 316, the second contact 326, the CESL 220, and the first ILD layer 222. A second ILD layer 230 is disposed over the ESL 228. In some embodiments, the ESL 228 may include silicon nitride or silicon oxynitride. The second ILD layer 230 may share the same composition with the first ILD layer 222. A gate contact via 234 extends through the second ILD layer 230 and the ESL 228 to contact the gate structure 214. A first contact via 334 extends through the second ILD layer 230 and the ESL 228 to contact the first contact 324. A second contact via 336 extends through the second ILD layer 230 and the ESL 228 to contact the second contact 326. The gate contact via 234, the first contact via 334 and the second contact via 336 may include a barrier layer and a metal fill layer disposed over the barrier layer. The barrier layer may include titanium nitride or tantalum nitride and functions to prevent electro-migration in the metal fill layer. The metal fill layer may include ruthenium (Ru), copper (Cu), nickel (Ni), cobalt (Co), or tungsten (W).

Reference is still made to FIG. 4. A third ILD layer 232 is disposed over the second ILD layer 230. The third ILD layer 232 may share the same composition with the first ILD layer 222. In some embodiments not explicitly shown in FIG. 4, another etch stop layer may be disposed between the second ILD layer 230 and the third ILD layer 232. A first metal line 236 and a second metal line 346 are disposed in the third ILD layer 232. The first metal line 236 is in direct contact with top surfaces of the gate contact via 234 and the first contact via 334, thereby electrically connecting them. The second metal line 346 is in direct contact with a top surface of the second contact via 336. In some embodiments, the second metal line 346 may resemble an island. In some other embodiments, the second metal line 346 may extend along the Y direction to couple to multiple contact vias that, like the second contact via, is coupled to a doped region similar to the second doped region 312. A connection via 348 is disposed over and in contact with the second metal line 346. The first metal line 236, the second metal line 346, and the connection via 348 may include a barrier layer and a metal fill layer over the barrier layer. The barrier layer may include titanium nitride or tantalum nitride and functions to prevent electro-migration in the metal fill layer. The metal fill layer may include copper (Cu), nickel (Ni), cobalt (Co), or tungsten (W). A third metal line 360 is disposed over the third ILD layer 232 and is in contact with a top surface of the connection via 348. The first metal line 236, the second metal line 346, the third metal line 360, and the connection via 348 may include a barrier layer and a metal fill layer over the barrier layer. The barrier layer may include titanium nitride or tantalum nitride and functions to prevent electro-migration in the metal fill layer. The metal fill layer may include copper (Cu), nickel (Ni), cobalt (Co), or tungsten (W). In one embodiment, the metal fill layer in the first metal line 236, the second metal line 346, the third metal line 360, and the connection via 348 includes copper (Cu).

When it comes to metallization layers in an interconnect structure, such as the frontside interconnect structure 140, conductive features in a metallization layer farther away from the FEOL structures are greater in dimension than those in a metallization layer closer to the FEOL structures. In FIG. 4, the third metal line 360 is farther away from the transistor 200 than the first metal line 236 and the second metal line 346. That is, the third metal line 360 has a much greater cross-sectional area than the first metal line 236 or the second metal line 346. The greater cross-sectional area of the third metal line 360 allows better thermal transmission from the device region 102. As shown in FIGS. 3 and 4, the third metal line 360 extends across the spacing S to couple to the frontside seal ring wall 104F of the seal ring 104. In some embodiments, the spacing S is between 100 μm and about 200 μm. This range is not trivial. When the spacing S is smaller than 100 μm, heat wave bounced back from the seal ring 104 may interfere with the outgoing heat wave from the device region 102. When the spacing S is greater than 200 μm, dimensions of the IC chip may be unnecessarily enlarged. In some alternative embodiments not explicitly illustrated in the figures, further connection vias may be disposed over the third metal line 360 and are used to couple to further metal lines over the third metal line 360. These further metal lines may also span across the spacing S to couple to different areas of the seal ring 104.

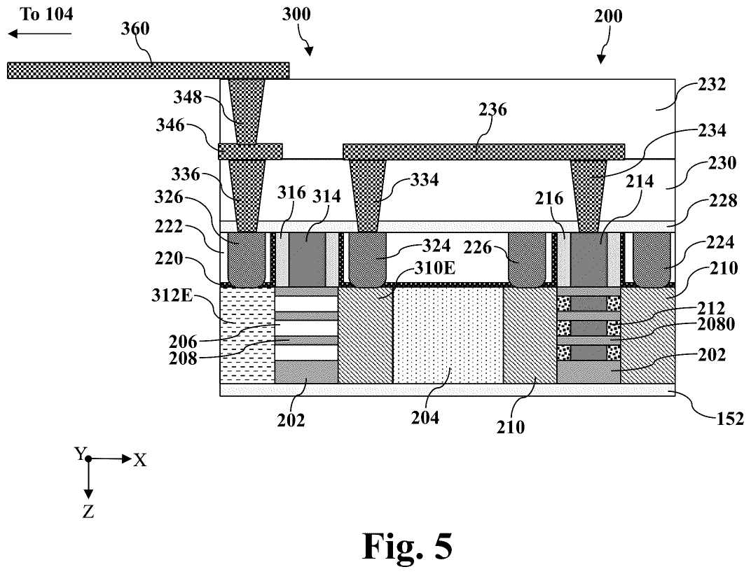

In the embodiments illustrated in FIG. 4, both the first doped region 310 and the second doped region 312 are formed by ion implantation. As shown in FIG. 4, the doped region 310 and the second doped region 312 may not extend all the way into the doped substrate portion 202. In some instances, they may not even extend into the bottommost second semiconductor layer 206. By forming the first doped region 310 and the second doped region 312 using ion implantation, the p-n junction transition may be more abrupt and the performance of the lateral diode 300 may be improved. In some alternative embodiments shown in FIG. 5, the first doped region 310 is replaced with a first epitaxial feature 310E and the second doped region 312 is replaced with a second epitaxial feature 312E. The first epitaxial feature 310E and the second epitaxial feature 312E are not formed by ion implantation. Instead, recesses are formed alongside the top gate spacer 316 to extend into the stack 207 and then separate epitaxial deposition processes are performed to form the first epitaxial feature 310E and the second epitaxial feature 312E. In the depicted embodiments, the first epitaxial feature 310E includes silicon (Si) and an n-type dopant, such as phosphorus (P) or arsenic (As) and the second epitaxial feature 312E includes silicon germanium (SiGe) and a p-type dopant, such as boron (B).

Reference is now made to FIGS. 4 and 5. The gate contact via 234 may draw heat away from the gate structure 214 of the transistor 200. The heat from the gate contact via 234 may then conduct to the first metal line 236, the first contact via 334, the first contact 324, the first doped region 310 (or the first epitaxial feature 310E in FIG. 5), the depletion region 311 below the dummy gate structure 314, the second doped region 312 (or the second epitaxial feature 312E in FIG. 5), the second contact 326, the second contact via 336, the second metal line 346, the connection via 348, the third metal line 360, and then finally to the seal ring 104. As described above, while heat can travel through the lateral diode 300 by conduction, the lateral diode 300 prevents electrically coupling between the gate structure 214 and the seal ring 104. The first doped region 310, the second doped region 312, and the depletion region 311 are formed of semiconductor materials, such as silicon or silicon germanium. As described above, their thermal conductivities are about two orders of magnitude greater than that of dielectric materials, such as silicon oxide. They are part of the heat conduction path to thermally couple the gate structure 214 to the frontside seal ring wall 104F of the seal ring 104.

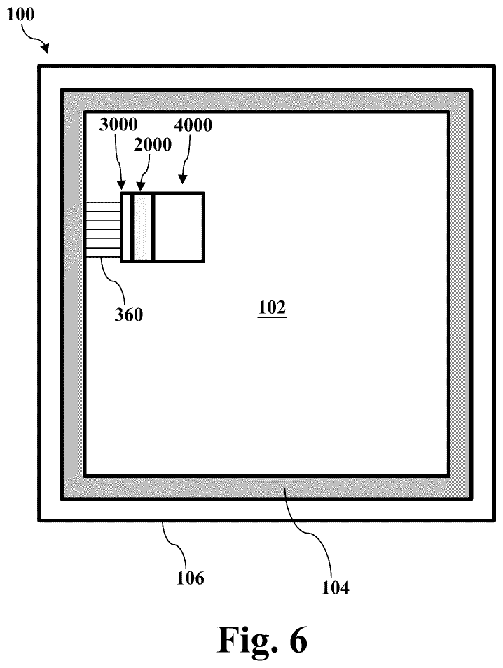

In very large scale integration (VLSI) circuit design, multiple transistors and may be grouped together to form standard cells that performed different circuit functions. FIG. 6 illustrates an example arrangement to efficiently conduct heat from the device region 102 to the seal ring 104 that surrounds the device region 102. Devices in the device region 102 may have a diode region 3000, a standard cell region 2000, and a memory region 4000 where the standard cell region 2000 is disposed between the diode region 3000 and the memory region 4000. In some embodiments, the diode region 300 may include an array of lateral diodes similar to the lateral diode 300 shown in FIG. 4 and FIG. 5. The standard cell region 2000 may include multiple standard cells that include transistors 200 that are functionally connected together. The memory region 4000 may include memory cells or macros. In some embodiments, the memory region 4000 includes static random access memory (SRAM) cells.

In one exemplary aspect, the present disclosure is directed to an integrated circuit (IC) chip. The IC chip includes a device region, an interconnect structure disposed over the device region, a seal ring surrounding the device region and the interconnect structure. The device region includes a transistor having a gate structure. The seal ring includes a metal structure. The gate structure is thermally coupled to the metal structure by way of a diode.

In some embodiments, the transistor is spaced apart from the seal ring by between about 100 μm and about 200 μm. In some embodiments, the transistor further includes a plurality of channel members extending between a source feature and a drain feature. The gate structure wraps around each of the plurality of channel members. The gate structure is spaced apart from the source feature and the drain feature by a plurality of inner spacer features. In some implementations, the diodes includes a well region, a stack disposed over the well region and including a plurality of first semiconductor layers interleaved by a plurality of second semiconductor layers, a first doped region and a second doped region in the stack, a first contact electrically coupled to the first doped region, and a second contact electrically coupled to the second doped region. In some instances, the well region includes silicon and a p-type dopant. In some embodiments, the gate structure is electrically coupled to the first doped region and the metal structure is electrically coupled to the second doped region. In some embodiments, the first doped region includes a first type dopant and the second doped region includes a second type dopant different from the first type dopant. In some embodiments, the first type dopant is an n-type dopant and the second type dopant is a p-type dopant. In some implementations, the IC chip further includes a gate contact via disposed on the gate structure, a first contact via disposed on the first contact, a second contact via disposed on the second contact, a first metal line disposed over the gate contact via and the first contact via, a second metal line disposed over the second contact via, a connection via disposed over the second metal line, and a third metal line disposed over the connection via. The third metal line is physically coupled to the metal structure of the seal ring.

In another exemplary aspect, the present disclosure is directed to a device structure. The device structure includes a backside dielectric layer, a transistor that includes a first well region disposed on the backside dielectric layer, a plurality of nanostructures disposed one over another over the first well region, and a gate structure wrapping around each of the plurality of nanostructures, a diode that includes a second well region disposed on the backside dielectric layer, a stack over the second well region and including a plurality of silicon layers interleaved by a plurality of silicon germanium layers, a first doped region and a second doped region in the stack and spaced apart by a depletion region, and a floating gate structure over the depletion region, and a seal ring metal structure spaced apart from the transistor by a spacing. The gate structure is electrically coupled to the first doped region. The second doped region is electrically coupled to the seal ring metal structure.

In some embodiments, the first well region and the second well region include a p-type dopant. In some implementations, the first doped region includes an n-type dopant and the second doped region includes a p-type dopant. In some instances, the spacing is between about 100 μm and about 200 μm. In some embodiments, the gate structure is electrically coupled to the first doped region by way of a gate contact via disposed on the gate structure, a first contact disposed on the first doped region, a first contact via disposed on the first contact, and a first metal line disposed on the gate contact via and the first contact via. In some embodiments, the second doped region is electrically coupled to the seal ring metal structure by way of a second contact disposed on the second doped region, a second contact via disposed on the second contact, a second metal line disposed on the second contact via, a connection via disposed on the second metal line, and a third metal line disposed on the connect via. In some implementations, the floating gate structure is electrically floating.

In yet another exemplary aspect, the present disclosure is directed to a device structure. The device structure includes a transistor that includes a plurality of nanostructures and a gate structure wrapping around each of the plurality of nanostructures, a diode that includes a stack having a plurality of first semiconductor layers interleaved by a plurality of second semiconductor layers, and a first doped region and a second doped region in the stack, and a seal ring metal structure spaced apart from the transistor by a spacing. The gate structure is electrically coupled to the first doped region. The second doped region is electrically coupled to the seal ring metal structure.

In some embodiments, the plurality of nanostructures include silicon, the plurality of first semiconductor layers include silicon, and the plurality of second semiconductor layers include silicon germanium. In some implementations, the first doped region includes an n-type dopant and the second doped region includes a p-type dopant. In some instances, the spacing is between about 100 μm and about 200 μm.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) chip, comprising:
a device region;
an interconnect structure disposed over the device region; and
a seal ring surrounding the device region and the interconnect structure,
wherein the device region comprises a transistor having a gate structure,
wherein the seal ring comprises a metal structure,
wherein the gate structure is thermally coupled to the metal structure by way of a diode.

2. The IC chip of claim 1, wherein the transistor is spaced apart from the seal ring by between about 100 μm and about 200 μm.

3. The IC chip of claim 1,
wherein the transistor further comprises a plurality of channel members extending between a source feature and a drain feature,
wherein the gate structure wraps around each of the plurality of channel members,
wherein the gate structure is spaced apart from the source feature and the drain feature by a plurality of inner spacer features.

4. The IC chip of claim 1, wherein the diode comprises:
a well region;
a stack disposed over the well region and comprising a plurality of first semiconductor layers interleaved by a plurality of second semiconductor layers;
a first doped region and a second doped region in the stack;
a first contact electrically coupled to the first doped region; and
a second contact electrically coupled to the second doped region.

5. The IC chip of claim 4, wherein the well region comprises silicon and a p-type dopant.

6. The IC chip of claim 4, wherein the gate structure is electrically coupled to the first doped region and the metal structure is electrically coupled to the second doped region.

7. The IC chip of claim 4,
wherein the first doped region comprises a first type dopant,
wherein the second doped region comprises a second type dopant different from the first type dopant.

8. The IC chip of claim 7,
wherein the first type dopant is an n-type dopant,
wherein the second type dopant is a p-type dopant.

9. The IC chip of claim 4, further comprising:
a gate contact via disposed on the gate structure;
a first contact via disposed on the first contact;
a second contact via disposed on the second contact;
a first metal line disposed over the gate contact via and the first contact via;
a second metal line disposed over the second contact via;
a connection via disposed over the second metal line; and
a third metal line disposed over the connection via,
wherein the third metal line is physically coupled to the metal structure of the seal ring.

10. A device structure, comprising:
a backside dielectric layer;
a transistor comprising:
a first well region disposed on the backside dielectric layer,
a plurality of nanostructures disposed one over another over the first well region, and
a gate structure wrapping around each of the plurality of nanostructures;
a diode comprising:
a second well region disposed on the backside dielectric layer,
a stack over the second well region and comprising a plurality of silicon layers interleaved by a plurality of silicon germanium layers,
a first doped region and a second doped region in the stack and spaced apart by a depletion region, and
a floating gate structure over the depletion region; and
a seal ring metal structure spaced apart from the transistor by a spacing,
wherein the gate structure is electrically coupled to the first doped region,
wherein the second doped region is electrically coupled to the seal ring metal structure.

11. The device structure of claim 10, wherein the first well region and the second well region comprise a p-type dopant.

12. The device structure of claim 10,
wherein the first doped region comprises an n-type dopant,
wherein the second doped region comprises a p-type dopant.

13. The device structure of claim 10, wherein the spacing is between about 100 μm and about 200 μm.

14. The device structure of claim 10, wherein the gate structure is electrically coupled to the first doped region by way of a gate contact via disposed on the gate structure, a first contact disposed on the first doped region, a first contact via disposed on the first contact, and a first metal line disposed on the gate contact via and the first contact via.

15. The device structure of claim 14, wherein the second doped region is electrically coupled to the seal ring metal structure by way of a second contact disposed on the second doped region, a second contact via disposed on the second contact, a second metal line disposed on the second contact via, a connection via disposed on the second metal line, and a third metal line disposed on the connect via.

16. The device structure of claim 10, wherein the floating gate structure is electrically floating.

17. A device structure, comprising:
a transistor comprising:
a plurality of nanostructures, and
a gate structure wrapping around each of the plurality of nanostructures;
a diode comprising:
a stack comprising a plurality of first semiconductor layers interleaved by a plurality of second semiconductor layers, and
a first doped region and a second doped region in the stack; and
a seal ring metal structure spaced apart from the transistor by a spacing,
wherein the gate structure is electrically coupled to the first doped region,
wherein the second doped region is electrically coupled to the seal ring metal structure.

18. The device structure of claim 17,
wherein the plurality of nanostructures comprise silicon,
wherein the plurality of first semiconductor layers comprise silicon,
wherein the plurality of second semiconductor layers comprise silicon germanium.

19. The device structure of claim 17,
wherein the first doped region comprises an n-type dopant,
wherein the second doped region comprises a p-type dopant.

20. The device structure of claim 17, wherein the spacing is between about 100 μm and about 200 μm.
